(19) United States
(12) Patent Application Publication
(10) Pub. No.: US 2008/0182427 A1
(43) Pub. Date: Jul. 31, 2008

(54) Deposition method for transition-metal oxide based dielectric

(76) Inventors: Lars Oberbeck, Dresden (DE); Uwe Schroeder, Dresden (DE); Johannes Heitmann, Dresden (DE); Stephan Kudelka, Dresden (DE); Tim Boescke, Dresden (DE); Jonas Sundqvist, Dresden (DE)

Correspondence Address: ESCHWEILER & ASSOCIATES LLC, NATIONAL CITY BANK BUILDING, CLEVELAND, OH, 44114, US

(21) Appl. No.: 11/698,337

(22) Filed: Jan. 26, 2007

(51) Int. Cl. H01L 29/78; H01L 21/31; H01L 29/92

(52) U.S. Cl. 438/785; 257/411; 257/532; 257/E29.342; 257/E21.24; 257/E29.255

(57) ABSTRACT

The present invention relates to a method for depositing a dielectric material comprising a transition metal oxide. In an initial step, a substrate is provided. In a further step, a first precursor comprising a transition metal containing compound, and a second precursor predominantly comprising at least one of water vapor, ozone, oxygen, or oxygen plasma are sequentially applied for depositing above the substrate a layer of a transition metal containing material. In another step, a third precursor comprising a dopant containing compound, and a fourth precursor predominantly comprising at least one of water vapor, ozone, oxygen, or oxygen plasma are sequentially applied for depositing above the substrate a layer of a dopant containing material. The transition metal comprises at least one of zirconium and hafnium. The dopant comprises at least one of barium, strontium, calcium, niobium, bismuth, magnesium, and cerium.

### BACKGROUND OF THE INVENTION

1. Field of the Invention

The present invention relates to a deposition method for a transition-metal oxide containing dielectric, and furthermore to a capacitor or transistor structure with a transition-metal oxide based dielectric, and a memory device comprising the same.

2. Description of the Related Art

Although in principle applicable to arbitrary integrated semiconductor structures, the following invention and the underlying problems will be explained with respect to integrated DRAM memory circuits in silicon technology.

Memory cells of a DRAM device each comprise a capacitor for storing information encoded as electric charge retained in the capacitor. A reliable operation of the memory cells demands for a minimal capacitance of the capacitors and a sufficiently long retention time of the charge in the capacitors.

There is a major interest to further reduce the lateral dimensions of structures of a DRAM to a minimal feature size of 40 nm and below. Therefore, in order not to reduce the capacitance of the DRAM capacitors, it is desirable to compensate shrinking lateral dimensions of the capacitors by providing a dielectric layer with a high specific dielectric constant, or k-value. Simultaneously, care has to be taken not to increase leakage currents, which lead to a short retention time of the DRAM memory cell and are influenced by the band gap of the dielectric material, and in particular by the match between the band structure of the dielectric to the band structure of the capacitor electrodes.

For DRAM capacitors at a feature size of below 40 nm, zirconium oxide (ZrO₂) and hafnium oxide (HfO₂) are considered likely candidates for providing a base material of the capacitor dielectric. In the cubic or tetragonal crystallization phase, pure ZrO₂ and HfO₂ each reach a specific dielectric constant of k=35 to 40. The dielectric constant as well as the leakage current density of ZrO₂ and HfO₂ films can be influenced by adding one or more additional oxide materials as dopants to the dielectric film. However, in many cases the addition of a given dopant that increases the specific dielectric constant leads also to an increase of leakage currents.

It would therefore be advantageous if a deposition method for a zirconium or hafnium oxide based dielectric film could be provided that achieves to increase the specific dielectric constant above that of pure ZrO₂ or HfO₂, respectively, while maintaining a low leakage current density. It would further be advantageous if a deposition method could be provided that enables depositing the film at a precisely defined thickness, composition, and crystallization phase over a high-aspect ratio structure.

### BRIEF SUMMARY OF THE INVENTION

According to a first aspect of the invention, a deposition method for a transition-metal oxide containing dielectric comprises:
providing a substrate;
applying sequentially a first precursor comprising a transition metal containing compound, and a second precursor predominantly comprising at least one of water vapor, ozone, oxygen, and oxygen plasma, for depositing above the substrate a layer of a transition metal containing material; and
applying sequentially a third precursor comprising a dopant containing compound, and a fourth precursor predominantly comprising at least one of water vapor, ozone, oxygen, and oxygen plasma, for depositing above the substrate a layer of a dopant containing material.

The transition metal used herein comprises at least one of zirconium and hafnium. The dopant used herein comprises at least one of barium, strontium, calcium, niobium, bismuth, magnesium, and cerium.

The method according to the invention uses two sets of precursors to deposit the transition metal oxide based material on the substrate. By the first set of precursors, a layer of transition metal containing material is deposited, while by the second set of precursors, a layer of dopant containing material is deposited. Each of the sets of precursors comprises water vapor, ozone, oxygen, or oxygen plasma as one of the precursors, which acts as oxidizing reactant with respect to the respective remaining precursor of each pair. The water vapor, ozone, oxygen, or oxygen plasma respectively sets free the transition metal of the first precursor and the dopant of the third precursor. A potential advantage of ozone is its higher cleaning effect, that is to say less residuals of the organic compounds of the first and third precursors remain in the dielectric film since ozone is capable of transforming organic parts of the first and third precursors into volatile gases. Water vapor, on the other hand, is potentially advantageous where clean separation of the organic parts of the precursors is desired without fragmenting the organic parts themselves.

By using in this way the technique known as Atomic Layer Deposition (ALD), the deposition method achieves a uniform distribution of both the transition-metal containing material and the dopant containing material across the surface of the substrate, even if the substrate is shaped in the form of a high-aspect-ratio structure, such as a structure comprising deep trenches for producing trench-type capacitors, or cylinder-or cup-type features for producing stacked-type capacitors.

As a result, the transition-metal containing material and the dopant containing material are deposited in defined quantities, each corresponding to a monolayer of one-molecule thickness or less, depending on the amount of sterical hindrance among the chosen precursor molecules, which limits coverage of the substrate surface by precursor molecules applied simultaneously. Since all atoms of the transition metal are placed in the immediate vicinity of a dopant atom in a highly controlled way, a temperature of the substrate, either during a separate annealing step or during the deposition process itself, can be chosen such that it induces rearrangement of neighboring atoms of the transition metal and dopant atoms together with oxygen atoms deposited in both monolayers in a common crystallization structure, in particular the perovskite structure, thus leading to the creation of a thin and precisely distributed film of high specific dielectric constant and low leakage current.

Preferred embodiments of the inventive deposition method are listed in the dependent claims 2 to 17.

A capacitor structure manufactured by the inventive method comprises a first and a second electrode of conducting material, with the dielectric film according to the invention disposed between both electrodes. The first and second electrodes each preferably are made of at least one of niobium nitride, titanium nitride, titanium silicon nitride, tantalum nitride, tantalum silicon nitride, tantalum carbide, carbon, tungsten, tungsten sulicide, ruthenium, ruthenium oxide, iridium, and iridium oxide. The dielectric film comprises zirconium or hafnium oxide and at least one of barium, strontium, calcium, niobium, bismuth, magnesium, and cerium. Preferably the dielectric film comprises a perovskite structure, which advantageously enables to provide both a high dielectric constant and a large bandgap, e.g. of 30-50 and 6 eV, respectively, in the case of SrZrO₃. The complete film or only part of it may have this structure. The orientation of the structure may vary within the film.

According to an embodiment, the dielectric film comprises a dopant content of between 5 and 70 atomic percent of the dielectric film material excluding oxygen. Preferably, in order to favor forming of a perovskite crystal structure, the dielectric film comprises a dopant content of between 50 and 70 atomic percent of the dielectric film material excluding oxygen.

A semiconductor memory device may comprise a plurality of memory cells each comprising the inventive capacitor.

### DESCRIPTION OF THE DRAWINGS

In the Figures:

FIG. 1a and 1b show schematic cross-sections of a substrate undergoing deposition of a dielectric film by a deposition method according to a first embodiment of the invention;

FIG. 2a shows a schematic cross-section of a substrate bearing a mixed dielectric film deposited by a method according to a second embodiment of the present invention;

FIG. 2b shows a schematic cross-section of a substrate bearing a nanolaminate dielectric film deposited by a method according to a third embodiment of the present invention; and

FIG. 3 shows a schematic cross-section of a trench-type capacitor formed by use of an embodiment of the inventive method.

FIG. 4 shows a schematic cross-section of a stacked-type capacitor formed by use of another embodiment of the inventive method.

In the Figures, like numerals refer to the same or similar functionality throughout the several views.

### DETAILED DESCRIPTION OF THE INVENTION

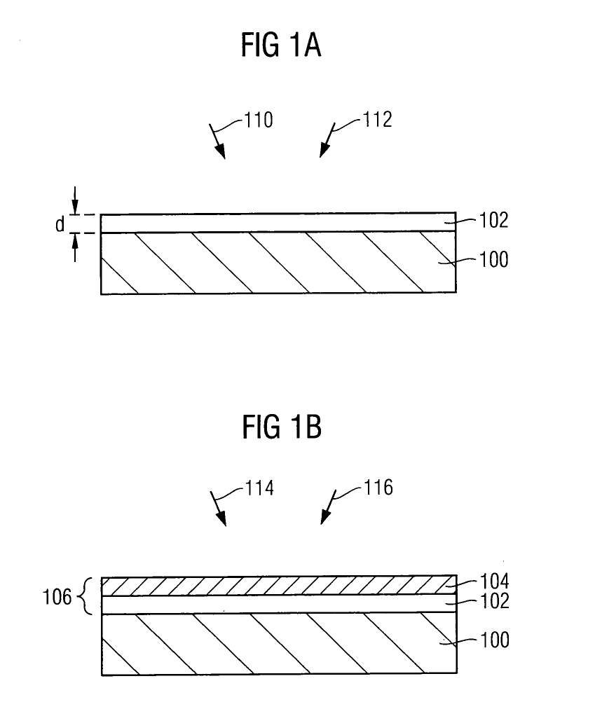

A deposition method according to a first embodiment is illustrated by making reference to FIGS. 1A and 1B. Initially, a substrate 100 is provided that is to serve as the base onto which a dielectric film is to be deposited. The substrate 100 can e.g. be a silicon wafer or a silicon wafer covered with a metallic electrode layer, such as a titanium nitride or tantalum nitride-based film, which may further contain silicon or one of the group containing carbon, niobium, tungsten, ruthenium and iridium. The substrate 100 may be a structured conductive layer, such as forming a bottom electrode of a capacitor.

As shown in FIG. 1A, after the initial provision of the substrate 100, in a first step of the present embodiment a thin dielectric layer 102 comprising zirconium oxide (ZrO₂) is deposited by an atomic layer deposition (ALD) method. After suitable substrate preparation, a first precursor 110 is introduced into a reaction chamber in which the Substrate 100 is placed. The first precursor 110 is a compound to which a zirconium atom is coupled. As is generally known from atomic layer deposition techniques, the first precursor 110 covers the surface of the substrate 100 in the form of a fraction of a one-molecule thick layer. After removing excess amounts of the first precursor 110 by means of a vacuum pump or flushing with an inert gas, in sequence as a second precursor 112, water vapor (H₂O) is introduced into the reaction chamber. Alternatively, also ozone (O₃) or oxygen or oxygen plasma may be used as the second precursor 112. Water, ozone, oxygen, and oxygen plasma act as reactants, oxidizing the part of the first precursor 110 that is attached to the surface of the substrate 100 and therefore has not been removed by the evacuation or purging before introducing the second precursor 112. Due to the oxidation, the zirconium is decoupled from the precursor compound and oxidized by the water vapor, ozone, oxygen, or oxygen plasma 112. Thus, a complete or fractional monolayer of zirconium oxide is formed on the substrate 100, where the degree of coverage depends on the amount of sterical hindrance between the molecules of the first precursor. The thickness d of the monolayer is determined by the molecular radius of zirconium oxide and lies in the range of approx. 0.4 nm. After the introduction of the first precursor 110, excess amounts of the second precursor 112 are now removed from the reaction chamber. Alternatively, the first and second precursors 110 and 114 can be introduced simultaneously into the reaction chamber to form a zirconium metal and strontium containing layer in a single step. After evacuation or purging, water vapor, ozone, oxygen or oxygen plasma 112, 116 are introduced to oxidize the zirconium and strontium containing layer.

As shown in FIG. 1B, a third precursor 114 comprising a strontium-containing compound is next introduced into the reaction chamber. In the same way as the first precursor covered the surface of the substrate 100 in the form of a, complete or fractional, monolayer, the third precursor 114 now covers the surface of the zirconium-containing monolayer 102, forming a further, complete or fractional, monolayer 104 of strontium-containing material. After an excess amount of the third precursor 114 has been removed from the reaction chamber, a fourth precursor 116 is introduced as a reactant to oxidize the third precursor 114, thus forming a monolayer 104 of strontium oxide stacked on top of the monolayer 102 of zirconium oxide. If both the monolayer 102 of zirconium oxide and the monolayer 104 of strontium oxide are fractional, e.g. each achieving a coverage of ⅓, substantially a mixed monolayer (not shown) of a coverage of approximately ⅔ for the example given will be formed. The reactant introduced as fourth precursor 116 may comprise at least one of water vapor, ozone, oxygen, or oxygen plasma. Preferably, the same reactant used as the second precursor is also used as the fourth precursor 116, thus simplifying the deposition method by reducing the number of different precursors that have to be provided.

As a result of carrying out the deposition method as described, a dielectric film 106 is deposited on the substrate 100, where the dielectric film 106 contains an approximately equal amount of zirconium oxide and strontium oxide. Since both of the zirconium oxide and the strontium oxide have been deposited in the form of stacked monolayers 102, 104, or in the form of at least one mixed monolayer as described above, by choosing the temperature of the substrate 100 during the deposition from a temperature range that is known to induce the formation of a given desired crystal structure comprising both zirconium and strontium along with oxygen, the dielectric film 106 is enabled to be formed in the desired crystallization structure. In particular, the mixed dielectric film 106 containing zirconium, strontium and oxygen can be provided in a crystallization structure such as the perovskite structure that is known to be associated with a desired set of properties including a high specific dielectric constant and large bandgap.

Optionally, a separate annealing step is performed after the deposition of the dielectric film, during which the substrate with the deposited dielectric film is heated to a defined temperature to induce crystallization in a desired crystallization structure. In this way, the duration of the annealing step and the choice of atmosphere in which to perform the annealing can be controlled in addition to the annealing temperature. Preferably, the annealing temperature lies between 200° C. and 1200° C., more preferably between 200° C. and 600° C. Suitable atmosphere gases include N₂, O₂, Ar, NH₃, and N₂O, with the annealing step lasting several seconds.

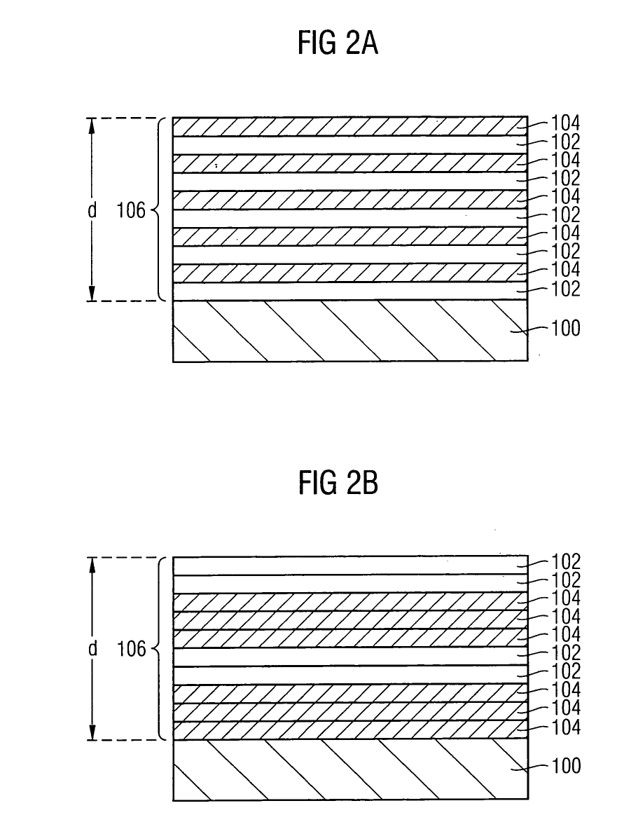

FIG. 2A shows a schematic cross-section of a dielectric film 106 that has been deposited by a deposition method according to a second embodiment of the invention, in which the monolayer deposition steps of FIG. 1A and FIG. 1B are carried out alternatingly in succession. For simplicity of display, it has been assumed that each deposition step results in a complete monolayer, thus leading to the deposition of a mixed dielectric film 106 in which monolayers 102 of zirconium oxide alternate with monolayers 104 of strontium oxide. If, depending on the choice of precursor, each deposition step results in a monolayer of fractional coverage, a mixed dielectric film 106 is deposited in which each monolayer itself contains both zirconium and strontium atoms in highly equal distribution.

By choosing a suitable number of repetitions in which the deposition steps of FIG. 1A and 1B are applied, a mixed dielectric film 106 is enabled to be deposited in a desired thickness d. For example, assuming a thickness of each monolayer 102, 104 of 0.4 nm, the mixed dielectric film 106 can be deposited to an overall thickness d of 8 nm by repeating alternatingly the deposition steps of FIG. 1A and 1B for ten times, thus leading to a stack of ten alternating monolayers 102, 104 as shown in FIG. 2A. If only fractional monolayers are deposited in each deposition step, the number of deposition steps to be performed has to be increased correspondingly to arrive at a dielectric layer of the same thickness.

Since throughout the dielectric film 106 zirconium atoms and strontium atoms are distributed in close proximity to each other as a result of the alternating deposition of complete or fractional monolayers 102, 104, by choosing the temperature of the substrate 100 during a subsequent annealing step or during the deposition process itself from a range that leads to desired common crystallization structure of zirconium, strontium and oxygen such as the perovskite structure, the present embodiment enables depositing a dielectric film 106 of desired thickness d throughout which zirconium, strontium and oxygen are crystallized in the desired common structure. For example, in the described way a mixed dielectric film 106 of zirconium strontium oxide in the perovskite crystallization structure is enabled to be deposited at a desired thickness, thus providing a dielectric film 106 that provides a high dielectric constant with a high resistance against leakage currents across the dielectric film 106.

FIG. 2B shows in schematic cross-section a dielectric film 106 that has been deposited by a deposition method according to a third embodiment of the invention. As in the embodiment of FIG. 2A, the deposition steps of FIG. 1A and FIG. 1B have been repeated in succession to deposit the dielectric film 106 as a sequence of ten separately deposited monolayers 102, 104. Again, for simplicity of display, it has been assumed that each deposition step results in a complete monolayer.

In this embodiment, however, the deposition steps of FIG. 1A and FIG. 1B are not applied alternatingly in succession. Instead, the deposition step of FIG. 1B has been applied three times in succession, followed by applying the deposition step of FIG. 1A two times in succession. Afterwards, the deposition step of FIG. 1B was again applied for three times in succession followed by applying the deposition step of FIG. 1A two times in succession. As shown in FIG. 2B, the resulting dielectric film 106 represents a nanolaminate of laminated sublayers, each combining several monolayers of zirconium oxide and strontium oxide, respectively. If only fractional moniolayers are deposited in each deposition step, correspondingly increasing the number of deposition steps to be repeated for creating each of the sublayers enables to arrive at a nanolaminate of the structure shown.

By choosing the temperature of the substrate 100, either during the deposition process or preferably during a separate annealing step, from a range of temperatures that enables the formation of desired crystallization structures within the sublayers of zirconium oxide and strontium oxide, respectively, and/or the formation of desired mixed crystallization structures in the vicinity of the interfaces between the sublayers, a dielectric film 106 can be deposited at a desired thickness d that combines a high overall dielectric constant with a high overall resistivity against leakage currents, e.g. by providing the sublayers of one of the oxide materials in a crystallization structure with a known high dielectric constant interspersed with the sublayers of the respective other one of the oxide materials in a crystallization structure that is known to provide a particularly high band-gap, thus forming an effective barrier against leakage currents.

Furthermore, by choosing a particular sequence of monolayers containing either zirconium or dopant a mixed film with a desired concentration ratio such as 1:2, 2:3, 3:4 etc. may be deposited. For example by repeating the sequence Sr—Zr—Sr—Sr—Zr, where Sr stands for a deposition step for a strontium containing monolayer and Zr stands for a deposition step for a zirconium containing monolayer, a mixed dielectric film with a concentration ratio of 3:2 between strontium and zirconium may be deposited, corresponding to a dopant content of approximately 60% of the atoms of the dielectric film material excluding oxygen. Preferably, the ratio is chosen such that the dopant content is between 5 and 70 atomic percent of the dielectric film material excluding oxygen, most preferably between 50 and 70 atomic percent. The most preferred range enables to form an advantageous perovskite structure in which vacant zirconium atom positions allow the zirconium atoms to move within a rigid structure of dopant, e.g. strontium, and oxygen atoms. This structure is highly polarizable and thus leads to a particularly high specific dielectric constant.

The reference to zirconium in the above described embodiments is purely exemplary. In alternative embodiments, hafnium may be used instead of zirconium, or in conjunction with zirconium, as a transition metal, carrying out the deposition method essentially as described. Likewise, the use of strontium as a dopant in the above embodiments as described is purely exemplary. In alternative embodiments, barium, calcium, niobium, bismuth, magnesium, or cerium, as well as combinations of any of these, may be used instead of or in conjunction with strontium, as a dopant while carrying out the deposition method essentially as described.

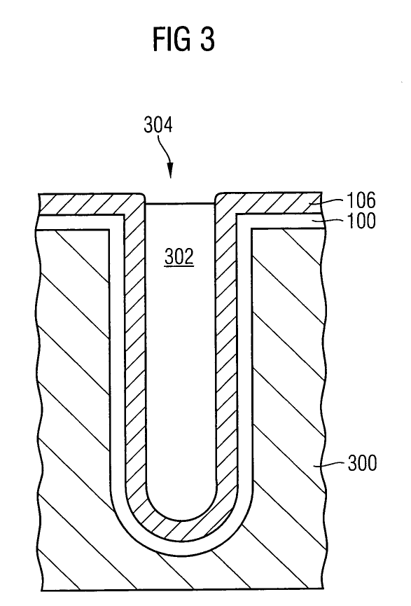

FIG. 3 shows a cross section of a trench-type capacitor structure formed by use of one of the above embodiments. The capacitor comprises a first electrode 100, a dielectric film 106 deposited by a deposition method of one of the above embodiments, and a second electrode 302. Preferably, the first electrode 100 contains at least one of titanium or tantalum. The dielectric 106 comprises zirconium or hafnium oxide, and a dopant oxide, preferably crystallized in a common crystallization structure. The thickness of the dielectric 106 is in a preferred embodiment about 2-20 nm.

In order to produce the capacitor structure shown, a trench 304 is formed into a substrate 300. The first electrode 100 is deposited on the surface of the trench 304 by a standard deposition technique. The dielectric 106 is applied directly on the first electrode 100 by one of the ALD processes taught along with the above embodiments. The second electrode 302 may be formed as polycrystalline silicon or a metallic electrode, preferably consisting of niobium nitride, titanium nitride, titanium silicon nitride, tantalum nitride, tantalum silicon nitride, tantalum carbide, carbon, tungsten, tungsten silicide, ruthenium, ruthenium oxide, iridium, or iridium oxide. These materials are electrical conductors well suited to function as electrodes of a capacitor. Their respective conduction bands are advantageously positioned such as to present a high resistivity of the interface of electrode and dielectric against leakage currents. Optionally, an interface layer of silicon nitride (not shown) is formed either between the first electrode 100 and the dielectric 106, or between the dielectric 106 and the second electrode, or both. Alternatively, for formation of a metal-insulator-silicon (MIS) instead of a metal-insulator-metal (MIM) structure, an interface layer of e.g. silicon nitride can be used between a silicon substrate and the dielectric 106, if a first electrode separate from the substrate is not used.

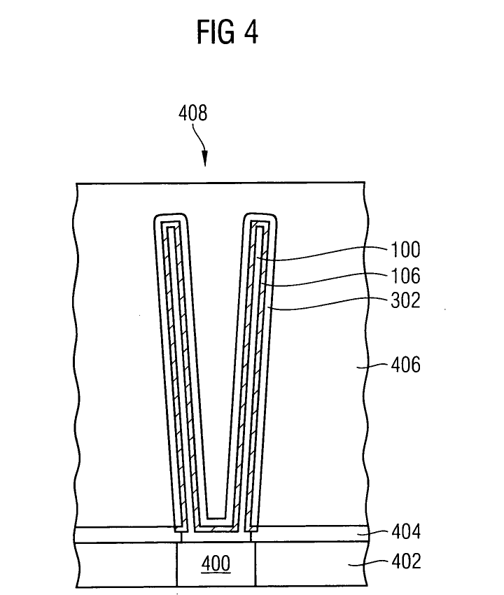

FIG. 4 shows a cross section of a stacked-type capacitor 408 structure formed by use of one of the above embodiments of the inventive deposition method. The stacked-type capacitor 408 comprises a cylinder-shaped first electrode 100, a dielectric 106 deposited on both the inside and outside of the first electrode 100 by a deposition method according to one of the above embodiments, and a second electrode 302. The dielectric 106 comprises a transition metal oxide and a dopant. The thickness of the dielectric 106 is in a preferred embodiment about 2-20 nm. A contact plug 400 is provided for connecting the first electrode 100. The contact plug 400 is initially formed in an insulating oxide layer 402 covered by a suitably patterned etch stop layer 404 by etching and filling with a conductive material. A conductive plate layer 406 covers the capacitor 408 structure.

Although the present invention has been described with reference to preferred embodiments, it is not limited thereto, but can be modified in various manners which are obvious for persons skilled in the art. Thus, it is intended that the present invention is only limited by the scope of the claims attached herewith.

For example, the ALD processes as illustrated in FIGS. 1A and 1B that are used to deposit respective layers of transition metal containing material and of dopant containing material may be substituted by pulsed chemical vapor deposition (pulsed CVD) processes, each respectively delivering a controlled pulse of a transition metal containing precursor and a dopant containing precursor into the reaction chamber. Between the pulses, the reaction chamber is cleaned out e.g. by flushing with an inert gas. The thickness of the thin layers formed by each CVD pulse may not as exactly defined as for the monolayers deposited by ALD processes, which makes ALD the preferred choice for the inventive deposition method.

1. A deposition method for making an integrated circuit having a transition metal oxide containing a dielectric film, the method comprising:
providing a substrate;
applying sequentially a first precursor comprising a transition metal containing compound, and a second precursor comprising at least one of water vapor, ozone, oxygen, and oxygen plasma, for depositing above the substrate a layer of a transition metal containing material; and
applying sequentially a third precursor comprising a dopant containing compound, and a fourth precursor comprising at least one of water vapor, ozone, oxygen, and oxygen plasma for depositing above the substrate a layer of a dopant containing material;
wherein the transition metal comprises at least one of zirconium and hafnium, and the dopant comprises at least one of barium, strontium, calcium, niobium, bismuth, magnesium, and cerium.

2. The deposition method according to claim wherein the first precursor and the third precursor are applied concurrently.

3. The deposition method according to claim 1 wherein at least one of the step of applying the first and second precursors, and the step of applying the third and fourth precursors is performed repeatedly for forming the dielectric film.

4. The deposition method according to claim 1 wherein the step of applying the first and second precursors, and the step of applying the third and fourth precursors are performed at a temperature of the substrate between 200° C. and 600° C.

5. The deposition method according to claim 1, further comprising a step of annealing at a temperature of the substrate after deposition of the dielectric film between 200° C and 1200° C.

6. The deposition method according to claim 1, further comprising a step of annealing the dielectric film in an atmosphere comprising at least one of N₂, 0₂, Ar, NH₃ and N₂0.

7. The deposition method according to claim 1 wherein the step of applying the first and second precursors, and the step of applying the third and fourth precursors are performed at substantially the same temperature of the substrate.

8. The deposition method according to claim 1 wherein the step of applying the first and second precursors, and the step of applying the third and fourth precursors are performed repeatedly in alternation.

9. The deposition method according to claim 1 wherein the step of applying the first and second precursors is repeated between one and fifty times, and the step of applying the third and fourth precursors is repeated between one and fifty times.

10. The deposition method according to claim 1, wherein the dielectric film is deposited at a thickness of between 2 and 50 nm.

11. The deposition method according to claim 1, wherein the dielectric film is formed comprising a dopant content between 5 and 70 atomic percent of the deposited material excluding oxygen.

12. The deposition method according to claim 1, further comprising forming a conducting layer in contact with the dielectric from at least one material selected from the group containing niobium nitride, titanium nitride, titanium silicon nitride, tantalum nitride, tantalum silicon nitride, tantalum carbide, carbon, tungsten, tungsten silicide, ruthenium, ruthenium oxide, iridium, and iridium oxide.

13. The deposition method according to claim 12, wherein the conducting layer is formed before forming the dielectric.

14. The deposition method according to claim 12, wherein the conducting layer is formed after forming the dielectric.

15. The deposition method according to claim 12, further comprising forming an interface layer comprising silicon nitride between the dielectric and the conducting layer.

16. The deposition method according to claim 1, wherein the first precursor comprises at least one compound selected from the group consisting of zirconium cyclopentadienyls, zirconium alkyl amides, hafnium cyclopentadienyls, and hafnium alkyl amides.

17. The deposition method according to claim 1, wherein the third precursor comprises at least one compound selected from the group consisting of alkylsilylamides, beta-diketonates, cyclopentadienyls, alkoxides, and alkylamides.

18. An integrated circuit having a capacitor structure comprising:
a first and a second electrode of conducting material;
a dielectric film comprising the transition metal oxide containing dielectric film disposed between the first and second electrodes, the transition metal oxide containing dielectric film comprising at least one of zirconium oxide and hafnium oxide, and at least one of barium, strontium, calcium, niobium, bismuth, magnesium, and cerium,
wherein the transition metal oxide containing dielectric film is formed by the process of:
applying sequentially a first precursor comprising a transition metal containing compound, and a second precursor comprising at least one of water vapor, ozone, oxygen, and oxygen plasma, for depositing above the substrate a layer of a transition metal containing material: and
applying sequentially a third precursor comprising a dopant containing compound, and a fourth precursor comprising at least one of water vapor, ozone, oxygen, and oxygen plasma for depositing above the substrate a layer of a dopant containing material;
wherein the transition metal comprises at least one of zirconium and hafnium, and the dopant comprises at least one of barium, strontium, calcium, niobium, bismuth, magnesium, and cerium.

19. The integrated circuit according to claim 18, wherein the conducting material of at least one of the first and second electrodes comprises at least one of niobium nitride, titanium nitride, titanium silicon nitride, tantalum nitride, tantalum silicon nitride, tantalum carbide, carbon, tungsten, tungsten silicide, ruthenium, ruthenium oxide, iridium, iridium oxide and highly doped silicon.

20. The integrated circuit according to claim 18, wherein the transition metal containing dielectric film comprises a perovskite structure.

21. The integrated circuit according to claim 18, wherein the transition metal containing dielectric film comprises a dopant content between 5 and 70 atomic percent of the dielectric film material excluding oxygen.

22. The integrated circuit according to claim 18, wherein the transition metal containing dielectric film comprises a dielectric constant greater than 40.

23. (canceled)

24. (canceled)

25. An integrated circuit including a transistor device, comprising:
source and drain regions;
a channel region;
a gate conductor and
a gate dielectric comprising a transition metal oxide containing dielectric film disposed between the gate conductor and the channel region, the gate dielectric comprising at least one of zirconium oxide and hafnium oxide, and at least one of barium, strontium, calcium, niobium, bismuth, magnesium, and cerium,
wherein the transition metal oxide containing dielectric film is formed by the process of:
applying sequentially a first precursor comprising a transition metal containing compound, and a second precursor comprising at least one of water vapor, ozone, oxygen, and oxygen plasma, for depositing above the substrate a layer of a transition metal containing material: and
applying sequentially a third precursor comprising a dopant containing compound, and a fourth precursor comprising at least one of water vapor, ozone, oxygen, and oxygen plasma for depositing above the substrate a layer of a dopant containing material:
wherein the transition metal comprises at least one of zirconium and hafnium, and the dopant comprises at least one of barium, strontium, calcium, niobium, bismuth, magnesium, and cerium.
